(19) United States
(12) Patent Application Publication
(10) Pub. No.: US 2023/0037374 A1
(43) Pub. Date: Feb. 9, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventor: Tatsuyoshi MIHARA, Tokyo (JP)

(21) Appl. No.: 17/847,984

(22) Filed: Jun. 23, 2022

(30) Foreign Application Priority Data
Aug. 3, 2021 (JP) 2021-127046

(51) Int. Cl. H01L 27/11597; H01L 27/11587

(52) U.S. Cl. CPC H01L 27/11597; H01L 27/11587

(57) ABSTRACT

A semiconductor device includes a plurality of word lines extending in a first direction in a plan view, a plurality of bit lines extending in a second direction orthogonal to the first direction in a plan view, and a plurality of memory cells arranged in matrix in the first direction and the second direction. The memory cell includes a gate insulating film, a lower layer electrode, a ferroelectric film, an upper layer electrode, and a pair of semiconductor regions, and a first width of the lower layer electrode in the first direction is larger than a second width of the upper layer electrode in the first direction in a plan view.

### CROSS-REFERENCE TO RELATED APPLICATIONS

The disclosure of Japanese Patent Application No. 2021-127046 filed on Aug. 3, 2021 including the specification, drawings and abstract is incorporated herein by reference in its entirety.

### BACKGROUND

The present invention relates to a semiconductor device and a method of manufacturing the same, for example, a semiconductor device having a ferroelectric film and a method of manufacturing the same.

As a memory element operated at a low voltage, a ferroelectric memory having a ferroelectric film has been known. In the ferroelectric memory, the write state and the erase state are determined in accordance with a polarization direction of the ferroelectric film. The ferroelectric memory has a high threshold and a low threshold corresponding to the polarization direction, and the width of both thresholds is referred to as a memory window. By widening the memory window, operational stability at the time of reading is improved.

Patent Document 1 and Non-Patent Document 1 disclose a transistor having an MFMIS (Metal-Ferroelectric-Metal-Insulator-Semiconductor) structure (hereinafter, may be referred to as a MISFET) constituting a ferroelectric memory. As shown in FIG. 25, the transistor of Non-Patent Document 1 includes a stacked structure composed of a gate insulating film GI, a lower layer electrode LE, a ferroelectric film FE, and an upper layer electrode UE, which are sequentially provided on a semiconductor substrate SUB, and a pair of semiconductor regions SR located on both sides of the stacked structure and provided in the semiconductor substrate. Also, the disclosure teaches that the operating voltage for obtaining the desired memory window (voltage applied to each part of the transistor at the time of writing and erasing) can be reduced by making the area ratio (SI/SF) of the area SI where the lower layer electrode LE overlaps with the gate insulating film GI and the area SF where the upper layer electrode UE overlaps with the ferroelectric film FE larger than 1. Namely, the area ratio (SI/SF) larger than 1 ((SI/SF)>1) is obtained by making the lengths of the lower layer electrode LE and the gate insulating film GI larger than the length of the upper layer electrode UE in the channel length direction LCH of the transistor.

Patent Document 1 discloses a self-alignment process for manufacturing the transistor having an MFMIS structure in which the area ratio (SI/SF) is larger than 1 ((SI/SF)>1) in the channel length direction LCH.

There are disclosed techniques listed below.
[Patent Document 1] U.S. Pat. No. 6,828,160
[Non-Patent Document 1] Proceedings of 79th Japan Society of Applied Physics Autumn Meeting (2018, Nagoya Congress Center) p. 20-141-11

### SUMMARY

The results of study by the inventors of this application will be shown below.

In order to operate the MISFET at high speed, it is necessary to increase the transconductance (gₘ) of the MISFET. Since the transconductance (gₘ) is a function of the ratio (W/L) of the channel width (W) and the channel length (L) of the MISFET, it is effective to make the channel length (L) as small as possible for improving the transconductance (gₘ). When the channel length (L) is reduced, the channel width (W) for obtaining a desired transconductance (gₘ) can also be reduced, and the MISFET can also be miniaturized.

In the case of the conventional technology shown in FIG. 25, in order to improve the reliability of the memory cell by making the area ratio (SI/SF) larger than 1 ((SI/SF)>1), the length of the lower layer electrode LE is made larger than the length of the upper layer electrode UE in the channel length direction LCH. However, it is difficult to make the dimension of the upper layer electrode UE in the channel length direction LCH smaller than the minimum processing dimension in the manufacturing process of transistor, and it is equal to or larger than the minimum processing dimension. Further, in order to make the area ratio (SI/SF) larger than 1 ((SI/SF)>1), the dimension of the lower layer electrode LE in the channel length direction needs to be further made larger than the dimension of the upper layer electrode UE in the channel length direction LCH. Namely, as the channel length (L) of the transistor is increased, it becomes indispensable to increase the channel width (W) in order to secure a desired transconductance (gₘ). As a result, there is a demerit that the size of the transistor in a plan view is enlarged.

In the semiconductor device having the ferroelectric memory, the improvement in reliability and the miniaturization of the MISFET having the MFMIS structure constituting the memory cell, in other words, the improvement in reliability and the miniaturization of the semiconductor device have been required.

The other problems and novel features will be apparent from the description of this specification and the accompanying drawings.

An outline of the typical embodiment disclosed in this application will be briefly described as follows.

A semiconductor device according to an embodiment includes a semiconductor substrate having a main surface, a plurality of word lines provided on the main surface and extending in a first direction in a plan view, a plurality of bit lines provided on the main surface and extending in a second direction orthogonal to the first direction in a plan view, and a plurality of memory cells arranged in matrix in the first direction and the second direction. Also, the memory cell includes a gate insulating film provided on the main surface, a lower layer electrode provided on the gate insulating film, a ferroelectric film provided on the lower layer electrode, an upper layer electrode provided on the ferroelectric film, and a pair of semiconductor regions provided so as to sandwich the lower layer electrode in the second direction, and a first width of the lower layer electrode in the first direction is larger than a second width of the upper layer electrode in the first direction in a plan view.

According to the embodiment, it is possible to achieve the improvement in reliability and miniaturization of the semiconductor device.

### BRIEF DESCRIPTION OF THE DRAWINGS

FIG. 1 is an equivalent circuit diagram of the principal part of the semiconductor device according to the present embodiment.

FIG. 2 is a plan view of the principal part of the semiconductor device according to the present embodiment.

FIG. 3 is a cross-sectional view taken along the line X1-X1′ and the line Y1-Y1′ in FIG. 2.

FIG. 4 is a plan view and a cross-sectional view showing the configuration of the principal part of the semiconductor device according to the present embodiment.

FIG. 5 is a table showing the voltages applied to each part of the semiconductor device according to the present embodiment in each of the write operation, the erase operation, and the read operation.

FIG. 6 is a cross-sectional view showing the manufacturing process of the semiconductor device according to the present embodiment.

FIG. 7 is a cross-sectional view showing the manufacturing process of the semiconductor device according to the present embodiment continued from FIG. 6.

FIG. 8 is a cross-sectional view showing the manufacturing process of the semiconductor device according to the present embodiment continued from FIG. 7.

FIG. 9 is a cross-sectional view showing the manufacturing process of the semiconductor device according to the present embodiment continued from FIG. 8.

FIG. 10 is a cross-sectional view showing the manufacturing process of the semiconductor device according to the present embodiment continued from FIG. 9.

FIG. 11 is a cross-sectional view showing the manufacturing process of the semiconductor device according to the present embodiment continued from FIG. 10.

FIG. 12 is a plan view corresponding to the manufacturing process of the semiconductor device according to the present embodiment shown in FIG. 11.

FIG. 13 is a cross-sectional view showing the manufacturing process of the semiconductor device according to the present embodiment continued from FIG. 11.

FIG. 14 is a cross-sectional view showing the manufacturing process of the semiconductor device according to the present embodiment continued from FIG. 13.

FIG. 15 is a cross-sectional view showing the manufacturing process of the semiconductor device according to the present embodiment continued from FIG. 14.

FIG. 16 is a cross-sectional view showing the manufacturing process of the semiconductor device according to the present embodiment continued from FIG. 15.

FIG. 17 is a cross-sectional view showing the manufacturing process of the semiconductor device according to the present embodiment continued from FIG. 16.

FIG. 18 is a cross-sectional view showing the manufacturing process of the semiconductor device according to the present embodiment continued from FIG. 17.

FIG. 19 is a cross-sectional view showing the configuration of the principal part of the semiconductor device according to the first modification.

FIG. 20 is a plan view and a cross-sectional view showing the configuration of the principal part of the semiconductor device according to the second modification.

FIG. 21 is a cross-sectional view showing the configuration of the principal part of the semiconductor device according to the second modification.

FIG. 22 is a cross-sectional view showing the manufacturing process of the semiconductor device according to the second modification.

FIG. 23 is a cross-sectional view showing the manufacturing process of the semiconductor device according to the second modification continued from FIG. 22.

FIG. 24 is a cross-sectional view showing the configuration of the principal part of the semiconductor device according to the third modification.

FIG. 25 is a cross-sectional view showing the configuration of the transistor according to the conventional technology.

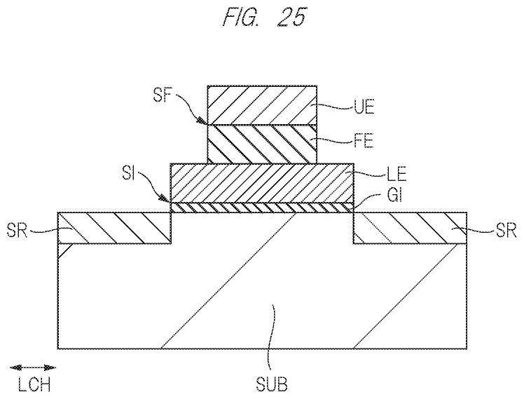

### DETAILED DESCRIPTION

In this specification, the invention will be described in a plurality of sections or embodiments when required as a matter of convenience. However, these sections or embodiments are not irrelevant to each other unless otherwise stated, and one relates to a part or all of the other as details, a modification, or supplement.

Also, in the embodiment described below, when mentioning the number of elements (including number of pieces, values, amount, range, and the like), the number of the elements is not limited to a specific number unless otherwise stated or except the case where the number is apparently limited to a specific number in principle, and the number larger or smaller than the specific number is also applicable.

Furthermore, in the embodiment described below, it goes without saying that each component (including an element step) is not indispensable unless otherwise clearly specified or unless it is obvious that the component is indispensable in principle.

Likewise, in the embodiment described below, when mentioning a shape, a positional relation, or the like of a component, a substantially approximate shape, a similar shape, or the like is included unless otherwise clearly specified or unless it is obvious from the context that the shape, the positional relation, or the like of the component differs in principle. The same applies to the above-described numerical value and range. Also, when mentioning “the lengths (or widths) of A and B are equal”, they are included in “equal” as long as they are intentionally made equal even if there are some errors due to the influence of the manufacturing process or the like.

Also, the same members are denoted by the same reference characters in principle throughout the drawings for describing the embodiment and the repetitive description thereof will be omitted. Also, hatching may be applied even in plan views so as to make them easy to see.

### Embodiment

The semiconductor device according to the present embodiment has a plurality of memory cells arranged in matrix in a memory cell array, and the memory cell is composed of a MISFET of an MFMIS structure having a ferroelectric film.

<Semiconductor Device>

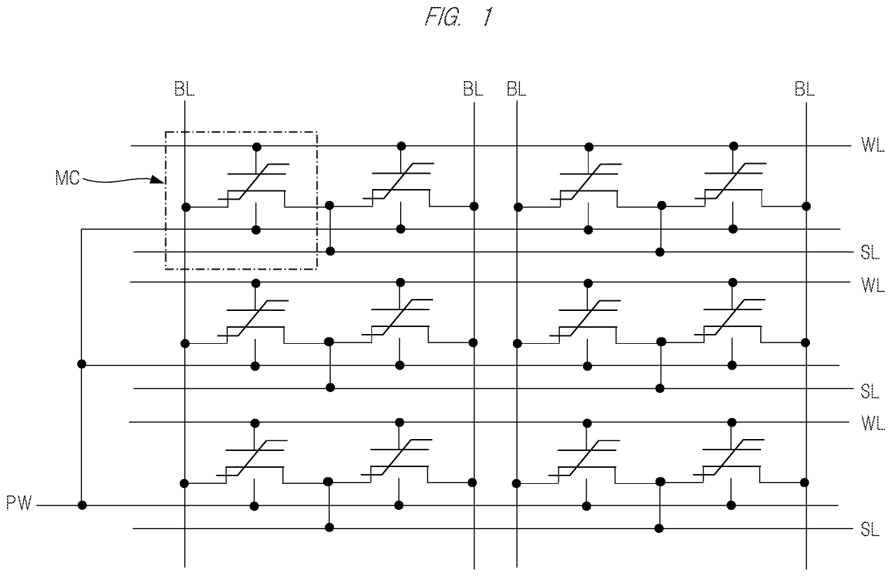

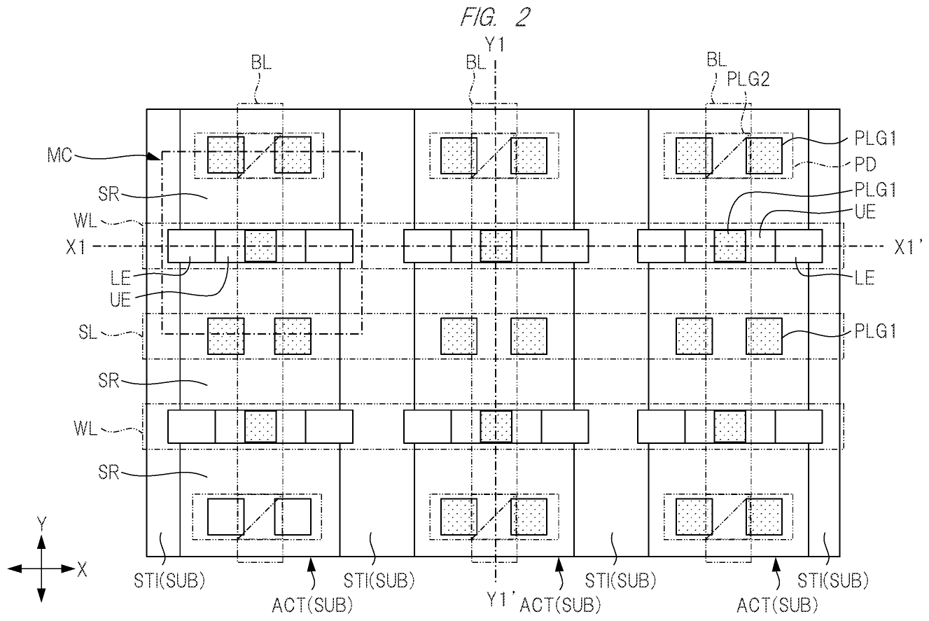

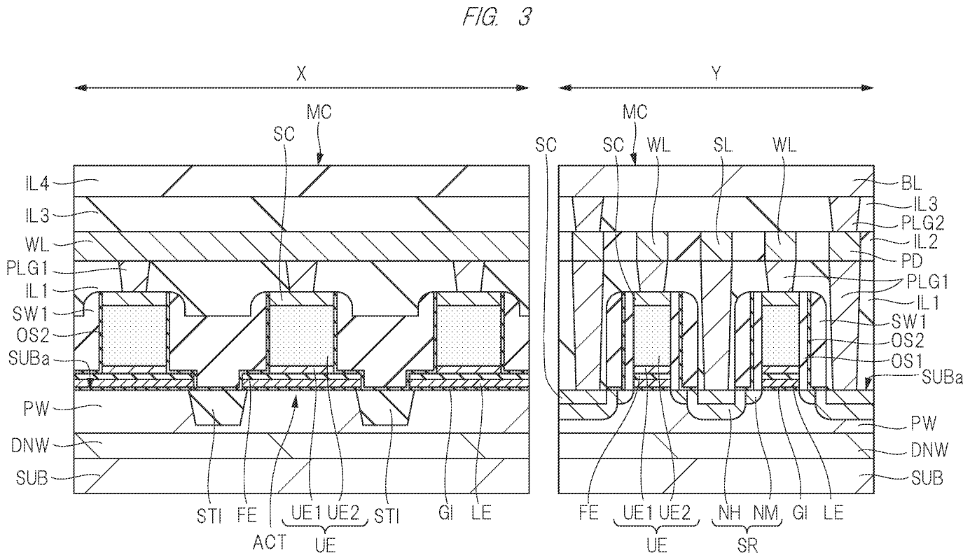

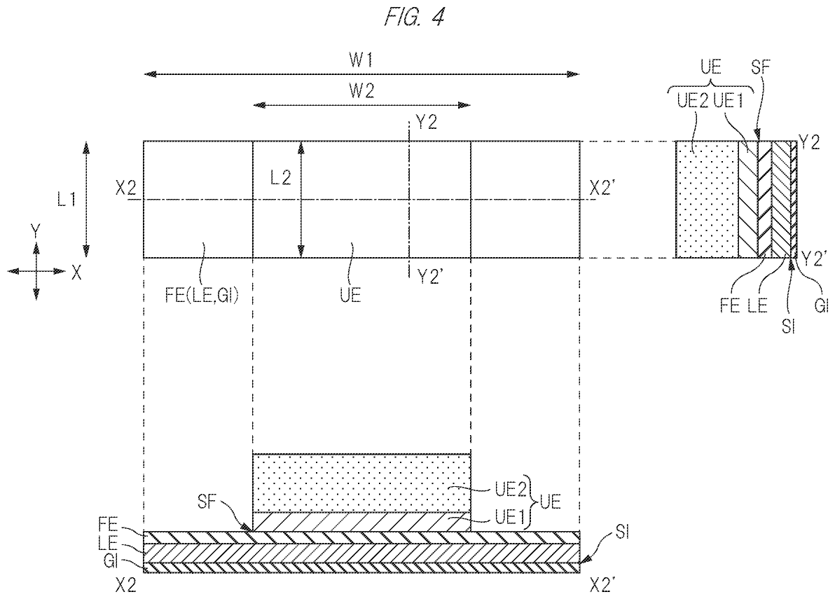

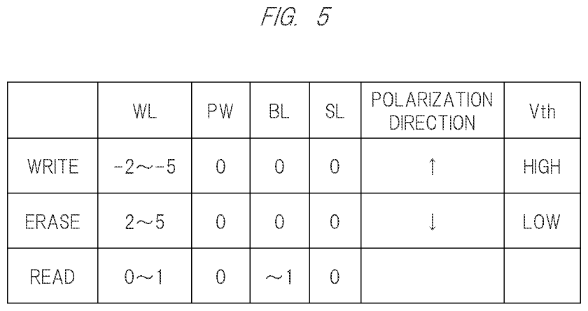

FIG. 1 is an equivalent circuit diagram of the principal part (memory cell array) of the semiconductor device according to the present embodiment. FIG. 2 is a plan view of the principal part (memory cell array) of the semiconductor device according to the present embodiment. FIG. 3 is a cross-sectional view taken along the line X1-X1′ and the line Y1-Y1′ in FIG. 2. FIG. 4 is a plan view and a cross-sectional view showing the configuration of the principal part of the semiconductor device according to the present embodiment. FIG. 5 is a table showing the voltages applied to each part of the semiconductor device according to the present embodiment in each of the write operation, the erase operation, and the read operation. In FIG. 2, the active region ACT, the element isolation film STI, the semiconductor region SR, the lower layer electrode LE, the upper layer electrode UE, the source line SL, the word line WL, the pad layer PD, the bit line BL, and the plug electrodes PLG1 and PLG2 are shown, and the other elements are omitted. Further, in FIG. 3, the cross-sectional view taken along the line X1-X1′ is shown as an X cross-sectional view, and the cross-sectional view taken along the line Y1-Y1′ is shown as a Y cross-sectional view.

As shown in FIG. 3, the memory cell MC includes the gate insulating film GI formed on the main surface SUBa of the semiconductor substrate SUB, the lower layer electrode LE provided on the gate insulating film GI, the ferroelectric film FE provided on the lower layer electrode LE, the upper layer electrode UE provided on the ferroelectric film FE, and a pair of semiconductor regions SR provided in the semiconductor substrate SUB. Note that the upper layer electrode UE has a stacked structure of the upper layer electrode UE1 provided on the ferroelectric film FE and the upper layer electrode UE2 provided on the upper layer electrode UE1. The memory cell MC is a MISFET, and the upper layer electrode UE functions as a gate and the pair of semiconductor regions SR functions as a source and a drain in terms of electrical characteristics.

As shown in FIG. 1, the plurality of memory cells MC are arranged in matrix to form the memory cell array. Each memory cell MC is connected to the word line WL, the bit line BL, the source line SL, and the p-type well region PW. The gate of the memory cell MC is connected to the word line, the drain is connected to the bit line, and the source is connected to the source line. As shown in FIG. 3, the memory cell MC is arranged in the p-type well region PW provided in the semiconductor substrate SUB, and a desired potential is supplied to the p-type well region PW.

As shown in FIG. 2, the element isolation film STI that defines the active region ACT is provided in the semiconductor substrate SUB. The element isolation film STI has a predetermined width in the X direction and extends in the Y direction. The plurality of element isolation films STI are arranged at predetermined intervals in the X direction. Also, the region sandwiched between the two element isolation films STI in the X direction functions as the active region ACT. Here, the X direction and the Y direction are directions orthogonal to each other.

The lower layer electrode LE extending in the X direction crosses the active region ACT, and both ends thereof are located on the two element isolation films STI sandwiching the active region ACT. The upper layer electrode UE is arranged on the lower layer electrode LE via the ferroelectric film FE shown in FIG. 3, and the upper layer electrode UE is connected to the word line WL extending in the X direction via the plug electrode PLG1. In the Y direction, a pair of semiconductor regions SR is arranged on both sides of the lower layer electrode LE, and one semiconductor region SR is connected to the source line SL extending in the X direction via the plug electrode PLG1 and the other semiconductor region SR is connected to the bit line BL extending in the Y direction via the plug electrode PLG1, the pad layer PD, and the plug electrode PLG2.

Next, the relationship between the lower layer electrode LE and the upper layer electrode UE will be described with reference to FIG. 4. As shown in the plan view of FIG. 4, the ferroelectric film FE, the lower layer electrode LE, and the gate insulating film GI are rectangles having the length L1 in the Y direction and the width W1 in the X direction, and the long sides and the short sides thereof overlap with each other. Alternatively, the configuration in which the long sides and the short sides of the ferroelectric film FE and the lower layer electrode LE overlap with each other and the long sides and the short sides of the gate insulating film GI are longer than the long sides and the short sides of the lower layer electrode LE is also possible. The upper layer electrode UE (upper layer electrodes UE1 and UE2) is a rectangle having the length L2 in the Y direction and the width W2 in the X direction. Here, the length L2 is equal to the length L1 (L2=L1), and the width W1 is larger than the width W2 (W1>W2). Namely, as shown in the plan view, the width W1 of the lower layer electrode LE is larger than the width W2 of the upper layer electrode UE in the X direction, and the length L1 of the lower layer electrode LE is equal to the length L2 of the upper layer electrode UE in the Y direction. With such a configuration, the area ratio (SI/SF) larger than 1 ((SI/SF)>1) can be achieved. Here, the area SF is the contact area between the ferroelectric film FE and the upper layer electrode UE, and the area SI is the contact area between the lower layer electrode LE and the gate insulating film GI. With the area ratio (SI/SF) larger than 1 ((SI/SF)>1), the operating voltage for obtaining a desired memory window (voltage applied to each part of the transistor at the time of writing and erasing) can be reduced, and the memory window can be expanded, so that the reliability of the read operation of the cell MC is improved. Further, the configuration to increase the area ratio (SI/SF) is not formed in the Y direction, and the length L2 of the upper layer electrode UE and the length L1 of the lower layer electrode LE are made equal to each other. This is for the purpose of reducing the size of the memory cell MC by reducing the gate length of the MISFET (transistor) constituting the memory cell MC shown in FIG. 2 and FIG. 3. As described above, by reducing the gate length of the MISFET, the gate width required to obtain the desired transconductance (gₘ) can be reduced. Namely, by reducing the length L1 of the lower layer electrode LE in the Y direction, the width W1 of the lower layer electrode LE in the X direction can be reduced, and the size (occupied area) of the MISFET constituting the memory cell MC can be reduced.

As shown in FIG. 3, the memory cell MC includes the gate insulating film GI formed on the main surface SUBa of the semiconductor substrate SUB, the lower layer electrode LE provided on the gate insulating film GI, the ferroelectric film FE provided on the lower layer electrode LE, the upper layer electrode UE provided on the ferroelectric film FE, and a pair of semiconductor regions SR provided in the semiconductor substrate SUB. The pair of semiconductor regions SR is two semiconductor regions SR arranged on both sides of the lower layer electrode LE so as to sandwich the lower layer electrode LE. The upper layer electrode UE has a stacked structure of the upper layer electrode UE1 provided on the ferroelectric film FE and the upper layer electrode UE2 provided on the upper layer electrode UE1.

The semiconductor region SR is composed of the n-type low-concentration semiconductor region NM and the n-type high-concentration semiconductor region NH. The plurality of memory cells MC are formed in the p-type well region PW provided in the p-type semiconductor substrate SUB via the n-type well region DNW. The n-type well region DNW is a region for separating the p-type well region PW from the p-type semiconductor substrate SUB, and includes the p-type well region PW.

The silicide layer SC is formed on the upper surface of the upper layer electrode UE (upper layer electrode UE2), and the upper layer electrode UE (upper layer electrode UE2) is connected to the word line WL via the plug electrode PLG1 in contact with the silicide layer SC. Further, the silicide layer SC is also formed on the upper surfaces of the pair of semiconductor regions SR, and one semiconductor region SR is connected to the source line SL via the plug electrode PLG1 in contact with the silicide layer SC. The other semiconductor region SR is connected to the bit wire BL via the plug electrode PLG1 in contact with the silicide layer SC, the pad layer PD provided on the plug electrode PLG1, and the plug electrode PLG2 in contact with the pad layer PD. As shown in the Y cross-sectional view of FIG. 3, the offset spacers OS1 and OS2 and the side wall insulating films SW1 are provided on the side walls of the stacked structure composed of the gate insulating film GI, the lower layer electrode LE, the ferroelectric film FE, and the upper layer electrode UE. Further, as shown in the X cross-sectional view of FIG. 3, the offset spacers OS2 and the side wall insulating films SW1 are provided on the side walls of the stacked structure composed of the gate insulating film GI, the lower layer electrode LE, the ferroelectric film FE, and the upper layer electrode UE, and the spaces between the adjacent upper layer electrodes UE are filled with the side wall insulating films SW1. Further, the interlayer insulating film IL1 is provided so as to cover the MISFETs constituting the memory cell MC, and the plurality of plug electrodes PLG1 are buried in the interlayer insulating film IL1. The interlayer insulating films IL2, IL3, and IL4 are stacked in this order on the interlayer insulating film IL1. The word line WL, the source line SL, and the pad layer PD which are the first layer wiring are buried in the interlayer insulating film IL2, the plurality of plug electrodes PLG2 are buried in the interlayer insulating film IL3, and the bit line BL which is the second layer wiring is buried in the interlayer insulating film IL4.

As shown in the X cross-sectional view of FIG. 3, the lower layer electrode LE and the upper layer electrode UE are independently provided for each memory cell MC. The lower layer electrodes LE of the adjacent memory cells MC are separated on the element isolation film STI in the X direction. Further, the upper layer electrodes UE of the adjacent memory cells MC are also separated from each other in the X direction, and the upper layer electrode UE of each memory cell MC is connected to the word line WL via the plug electrode PLG1. In this way, by separating the lower layer electrodes LE (or the lower layer electrodes LE and the upper layer electrodes UE) in the adjacent memory cells MC, electrical interference between the adjacent memory cells MC can be suppressed.

Next, each element shown in FIG. 3 will be described. The semiconductor substrate SUB is, for example, a single crystal silicon substrate, and the specific resistance thereof is, for example, 1 Ω·cm or more and 10 Ω·cm or less. The element isolation film STI is, for example, a silicon oxide film, but may have a stacked structure of a thin silicon nitride film and a thick silicon oxide film. The gate insulating film GI is, for example, a stacked film having a silicon oxide film and a hafnium oxide film. The hafnium oxide film is formed on the silicon oxide film, and the thickness of the gate insulating film GI is, for example, 1 nm or more and 3 nm or less.

The lower layer electrode LE and the upper layer electrode UE1 are preferably made of a metal film such as titanium nitride, tantalum nitride, or tungsten. The film thickness of the lower layer electrode LE and the upper layer electrode UE1 is, for example, 1 nm to 5 nm. The ferroelectric film FE has the property that a dielectric polarization occurs when an electric field is applied and the polarization state is then retained even when the application of the electric field is stopped. The crystal structure of the ferroelectric film FE is mainly an orthorhombic system, whereby the ferroelectric property can be obtained. The material of the ferroelectric film FE has a higher dielectric constant than silicon nitride and is, for example, a hafnium oxide film containing hafnium (Hf) and oxygen (O). The ferroelectric film FE may further contain zirconium (Zr), silicon (Si), germanium (Ge), yttrium (Y), lanthanum (La), or ytterbium (Yb).

The upper layer electrode UE2 is, for example, a polycrystalline silicon film containing an impurity such as phosphorus (P) or boron (B). The silicide layer SC is made of, for example, cobalt silicide, nickel silicide, platinum silicide, or nickel platinum silicide.

The offset spacer OS1 and the side wall insulating film SW1 are made of, for example, a silicon nitride film, and the offset spacer OS2 is made of, for example, a silicon oxide film. The interlayer insulating films IL1 to IL4 are, for example, silicon oxide films, but may have a stacked structure of a silicon nitride film and a silicon oxide film on the silicon nitride film. The plug electrode PLG1 is made of, for example, tungsten. The word line WL, the source line SL, the pad layer PD, and the bit line BL are, for example, copper wiring, and are composed of a stacked film of copper (Cu) as a main material and a barrier layer (for example, titanium nitride (TiN), tantalum nitride (TaN), or the like) for suppressing the diffusion of the copper. Note that the plug electrode PLG2 is composed of a stacked film of copper (Cu) and a barrier layer, and the bit line BL and the plug electrode PLG2 have an integrated structure formed by using the dual damascene method.

<Operation of Memory Cell MC>

The operation of the memory cell MC will be described with reference to FIG. 1 and FIG. 5. The voltages shown in FIG. 5 are applied to each part of the memory cell MC at the time of the operations of “write”, “erase”, and “read”. In the write operation, −2 to −5 V is applied to the word line WL and 0 V is applied to the p-type well region PW, the bit line BL, and the source line SL, thereby setting the polarization direction of the ferroelectric film FE to the first polarization state. In the first polarization state, the polarization direction is the direction from the lower layer electrode LE toward the upper layer electrode UE, and the threshold value (Vth) of the MISFET of the memory cell MC becomes a high threshold value. In the erase operation, 2 to 5 V is applied to the word line WL and 0 V is applied to the p-type well region PW, the bit line BL, and the source line SL, thereby setting the polarization direction of the ferroelectric film FE to the second polarization state. In the second polarization state, the polarization direction is the direction from the upper layer electrode UE toward the lower layer electrode LE, and the threshold value (Vth) of the MISFET of the memory cell MC becomes a low threshold value. In the read operation, 0 to 1 V is applied to the word line WL, 1 V or less is applied to the bit line BL, and 0 V is applied to the p-type well region PW and the source line SL, and the drain current is measured to detect the write state or the erase state.

### Features of Semiconductor Device According to Present Embodiment

As shown in FIG. 4, the operating voltage for obtaining the desired memory window (voltage applied to each part of the transistor at the time of writing and erasing) can be reduced by achieving the area ratio (SI/SF) larger than 1 ((SI/SF)>1) by increasing the width W1 of the lower layer electrode LE with respect to the width W2 of the upper layer electrode UE in the X direction, and the power consumption of the semiconductor device can be reduced. Further, since the memory window obtained for the desired operating voltage can be widened, the reliability of the semiconductor device can be improved.

As shown in FIG. 2 to FIG. 4, by forming the configuration in which the area ratio (SI/SF) larger than 1 ((SI/SF)>1) is achieved only in the X direction and the length L1 of the lower layer electrode LE is made equal to the length L2 of the upper layer electrode UE in the Y direction, the channel length (L) of the MISFET constituting the memory cell MC can be reduced, and thus the channel width (W) for obtaining the desired transconductance (gₘ) can be reduced. Therefore, the size of the memory cell MC (occupied area of the memory cell MC) can be reduced, and the semiconductor device can be miniaturized.

Further, as shown in FIG. 2 and FIG. 3, by independently providing the lower layer electrode LE (or the lower layer electrode LE and the upper layer electrode UE) for each memory cell MC in the X direction, electrical interference between the adjacent memory cells MC can be suppressed. For example, when one of the adjacent memory cells MC connected to the word line WL is in the “first polarization state” and the other is in the “second polarization state”, the lower layer electrodes LE of these memory cells MC have different potentials. If the lower layer electrodes LE of the adjacent memory cells MC are connected, the potential of the lower layer electrode LE of one memory cell MC is affected by the potential of the lower layer electrode LE of the other memory cell MC, so that the data retention characteristics (data retention time) of the memory cell MC are deteriorated. In the semiconductor device according to the present embodiment, since the lower layer electrodes LE (or the lower layer electrodes LE and the upper layer electrodes UE) are separated, the data retention characteristics of the memory cell MC can be improved, and the reliability of the semiconductor device can be improved.

As shown in FIG. 3, the upper layer electrode UE is composed of the upper layer electrode UE1 made of a metal film provided on the ferroelectric film FE and the upper layer electrode UE2 made of a polycrystalline silicon film provided on the upper layer electrode UE1. Since the upper layer electrode UE1 made of a metal film is interposed between the ferroelectric film FE and the upper layer electrode UE2 made of a polycrystalline silicon film, it is possible to prevent the occurrence of the defect that the upper layer electrode UE2 made of a polycrystalline silicon film is depleted and the voltage applied to the ferroelectric film FE at the time of “writing” or “erasing” is reduced.

<Method of Manufacturing Semiconductor Device>

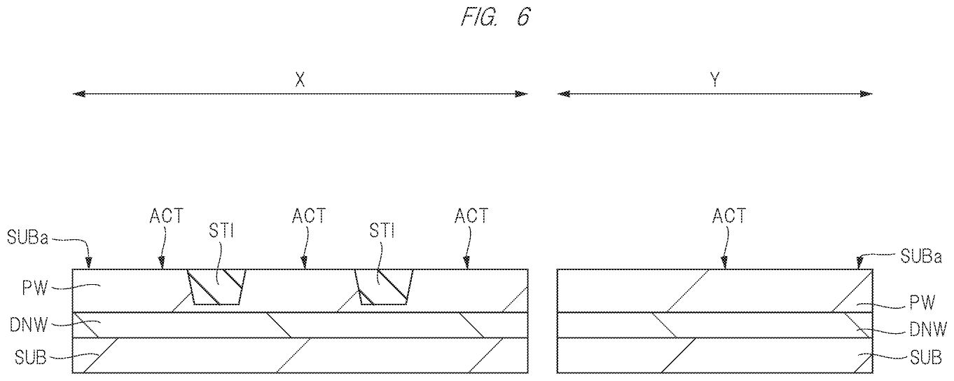

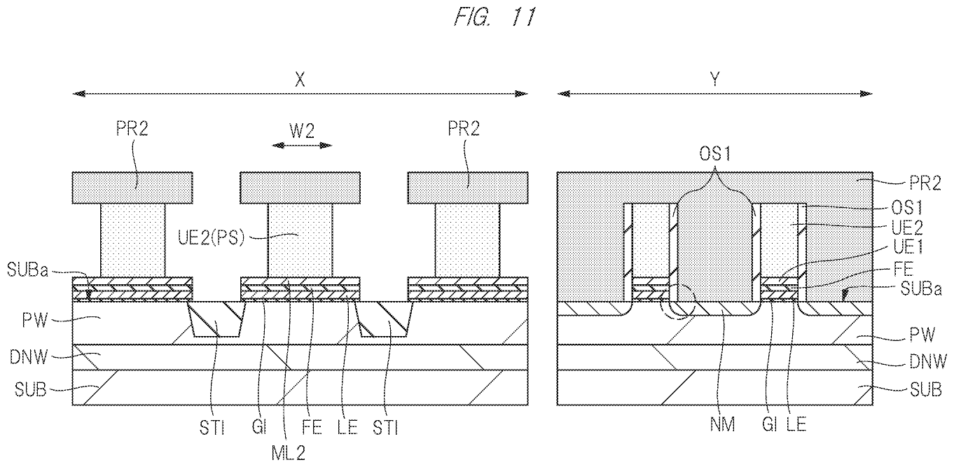

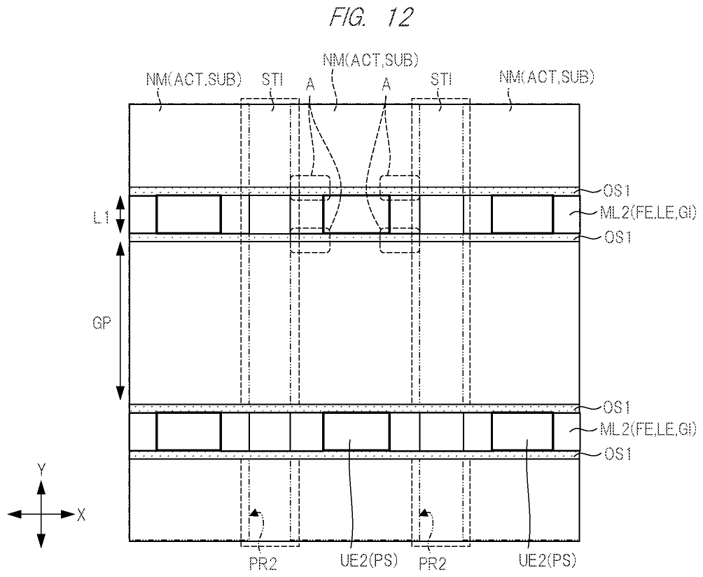

FIG. 6 to FIG. 11 and FIG. 13 to FIG. 18 are cross-sectional views showing the manufacturing process of the semiconductor device according to the present embodiment, and FIG. 12 is a plan view corresponding to the manufacturing process of the semiconductor device according to the present embodiment shown in FIG. 11.

As shown in FIG. 6, the p-type semiconductor substrate SUB is prepared. The p-type well region PW is provided on the side of the upper surface SUBa of the semiconductor substrate SUB. Also, the n-type well region DNW for separating the p-type well region PW from the semiconductor substrate SUB is provided below the p-type well region PW in the depth direction. Further, the element isolation films STI having a desired depth from the main surface SUBa are selectively formed in the semiconductor substrate SUB, and the region sandwiched by the element isolation films STI functions as the active region ACT.

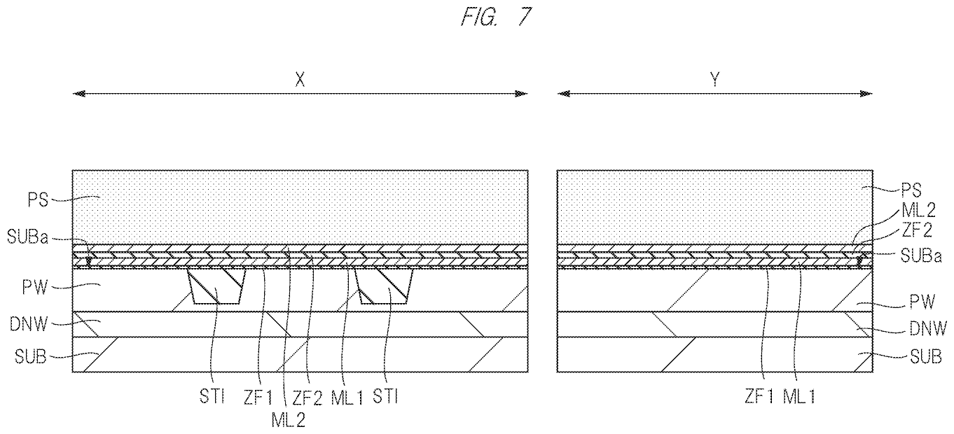

Next, as shown in FIG. 7, the insulating film ZF1, the metal film ML1, the insulating film ZF2, the metal film ML2, and the polycrystalline silicon film (conductor film) PS are sequentially deposited on the main surface SUBa of the semiconductor substrate SUB. By processing (patterning) the insulating film ZF1, the metal film ML1, the insulating film ZF2, the metal film ML2, and the polycrystalline silicon film (conductor film), the gate insulating film GI, the lower layer electrode LE, the ferroelectric film FE, the upper layer electrode UE1, and the upper layer electrode UE2 described with reference to FIG. 3 are formed. The patterning is, for example, to process the films to be processed into a desired pattern by the photolithography process and the etching process.

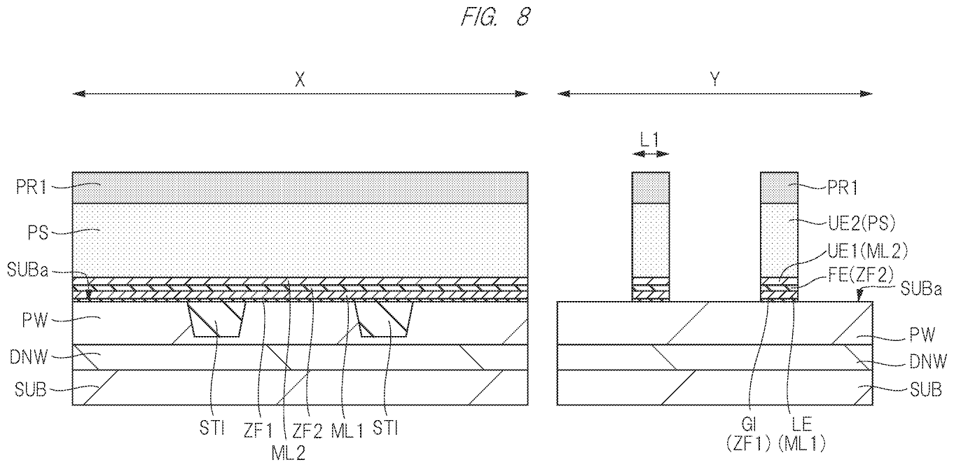

Next, as shown in FIG. 8, the polycrystalline silicon film PS, the metal film ML2, the insulating film ZF2, the metal film ML1, and the insulating film ZF1 are patterned in the Y direction by using the photoresist layer PR1. Then, the first structure (first stacked structure) having the length L1 in the Y direction and extending in the X direction is formed. In the Y direction, the first structure includes the gate insulating film GI, the lower layer electrode LE, the ferroelectric film FE, the upper layer electrode UE1, and the upper layer electrode UE2 formed in this order from the side of the main surface SUBa of the semiconductor substrate SUB. Next, the photoresist layer PR1 is removed.

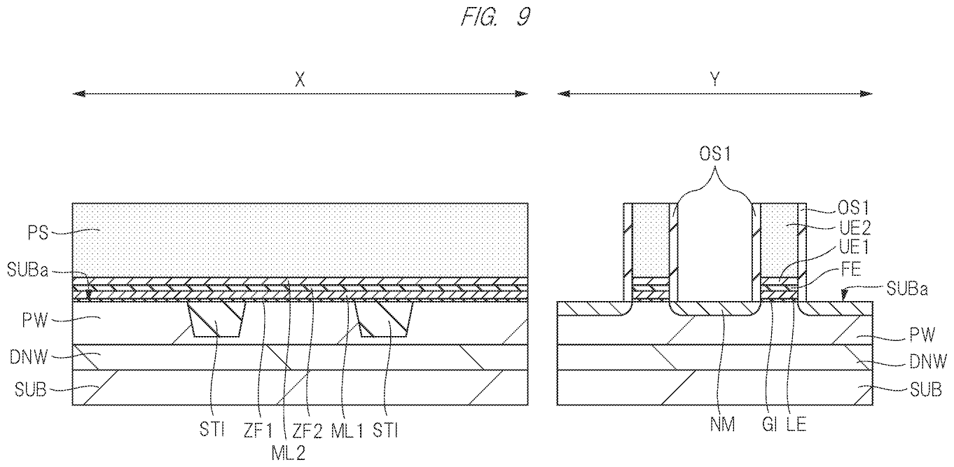

Next, as shown in FIG. 9, the offset spacers OS1 are formed on the side walls of the first structures. Although not shown, in the Y cross-sectional view, the offset spacers OS1 are selectively formed on the side walls of the first structures by depositing an insulating film so as to cover the upper layer electrodes UE2 and performing the anisotropic dry etching to the insulating film. Next, in the Y cross-sectional view, the n-type low-concentration semiconductor regions NM are formed in the semiconductor substrate SUB so as to sandwich the first structure.

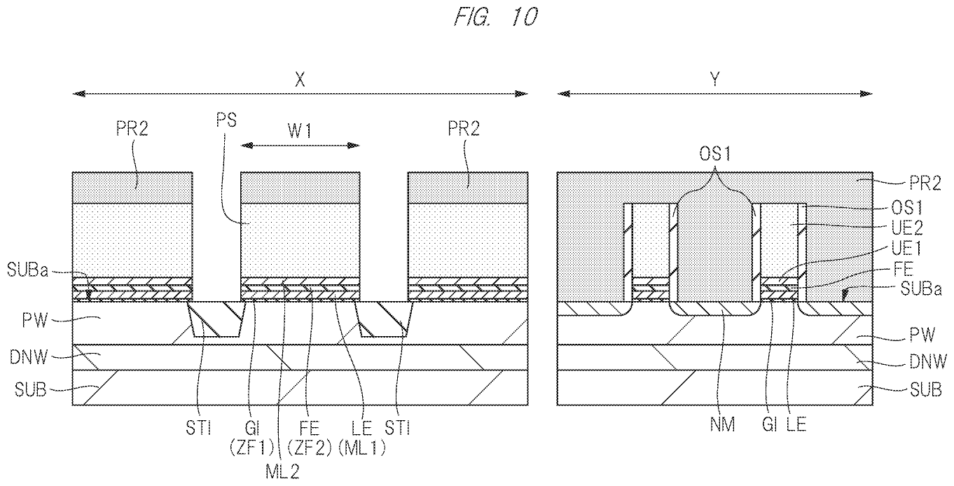

Next, as shown in FIG. 10, the above-mentioned first structure is patterned to form the second structure (second stacked structure) having the width W1 in the X direction. The second structure includes the gate insulating film GI, the lower layer electrode LE, the ferroelectric film FE, the metal film ML2, and the polycrystalline silicon film PS formed in this order from the side of the main surface SUBa of the semiconductor substrate SUB. In the X direction, the second structure extends on the active region ACT shown in FIG. 6 and its ends are terminated on the element isolation films STI that define the active region ACT.

Next, as shown in FIG. 11 and FIG. 12, the polycrystalline silicon film PS is thinned in the X direction to form the upper layer electrode UE2. As shown in FIG. 11 and FIG. 12, the photoresist layer PR2 has a space above the element isolation film STI in the X direction. Isotropic etching is performed to the side wall of the polysilicon film PS by supplying the etching gas from this space, so that the polysilicon film PS is thinned to form the upper layer electrode UE2. The polycrystalline silicon film PS having the width W1 in the X direction becomes the upper layer electrode UE2 reduced to the width W2 by the thinning process. By forming the upper layer electrode UE2 having the width W2 without using the photolithography process, the manufacturing cost can be reduced.

Further, as shown in FIG. 11 and FIG. 12, the side wall of the first structure is covered with the offset spacer OS1 in the Y direction, and it is thus possible to prevent the main surface SUBa of the semiconductor substrate SUB from being etched in the active region ACT. When the offset spacer OS1 is not provided, there is a risk that the main surface SUBa of the semiconductor substrate SUB is etched by the etching gas via the interface between the first structure and the photoresist layer PR2 as the polycrystalline silicon film PS is thinned in the isotropic etching process. For example, this problem is likely to occur in portions A of FIG. 12 (shown only in one memory cell MC). Next, the photoresist layer PR2 is removed.

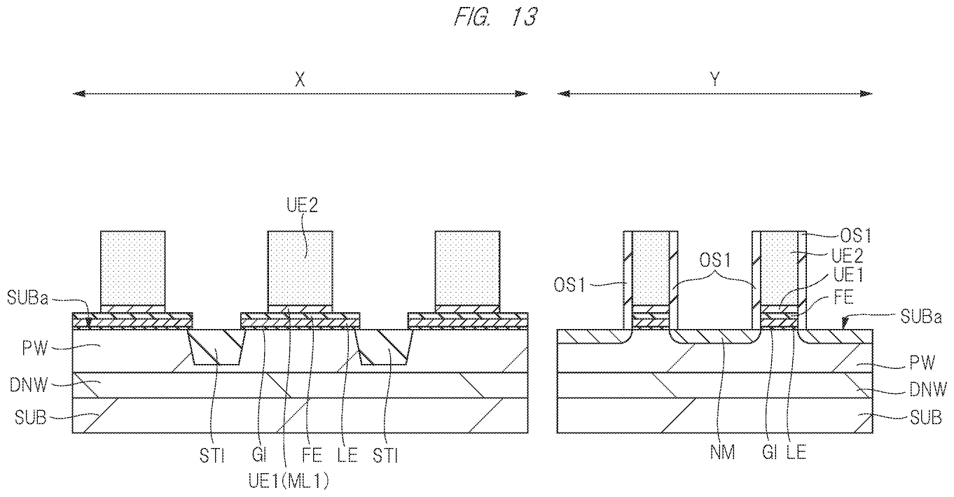

Next, as shown in FIG. 13, the metal film ML2 in the region exposed from the upper layer electrode UE2 is etched to form the upper layer electrode UE1 in the region covered with the upper layer electrode UE2. Namely, the upper layer electrode UE1 has the width W2 equal to that of the upper layer electrode UE2 in the X direction.

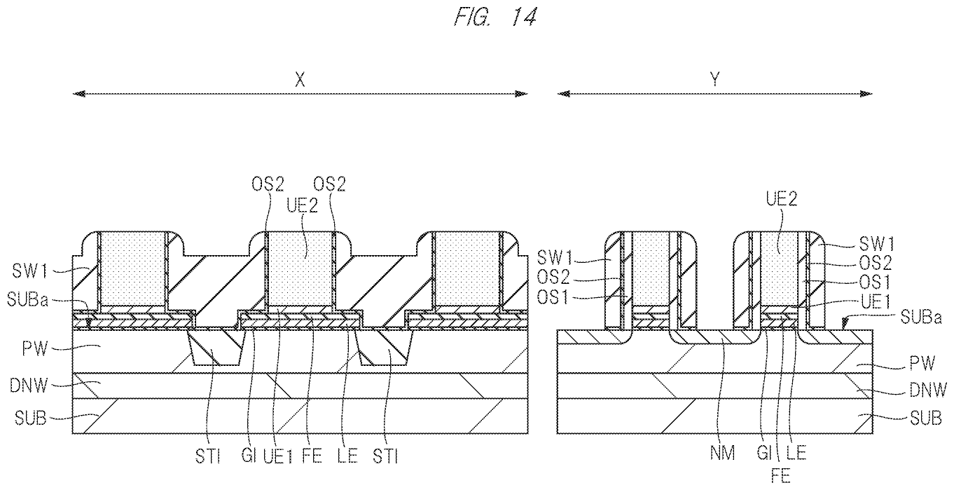

Next, a stacked film of a silicon oxide film and a silicon nitride film is deposited on the main surface SUBa of the semiconductor substrate SUB, and the anisotropic dry etching is performed to the stacked film, thereby forming the offset spacer OS2 and the side wall insulating film SW1 shown in FIG. 14. Here, as shown in FIG. 12, the interval (length L1) of the offset spacers OS1 sandwiching the upper layer electrode UE2 in the Y direction is sufficiently narrower than the interval GP of the offset spacers OS1 formed on the side walls of the adjacent upper layer electrodes UE2 in the Y direction. Therefore, by setting the film thickness d of the stacked film so as to satisfy (L1)/2<d<GP/2, the space between the two adjacent upper layer electrodes UE2 can be filled with the stacked film in the X direction, and the main surface SUBa of the semiconductor substrate SUB can be exposed between the two adjacent upper layer electrodes UE2 in the Y direction. By filling the space between the two adjacent upper layer electrodes UE2 in the X direction with a stacked film, the manufacturing yield of the semiconductor device can be improved. This is because if a cavity called “blowhole” is formed in the stacked film between two adjacent upper layer electrodes UE2 in the X direction, it becomes a factor of lowering the manufacturing yield.

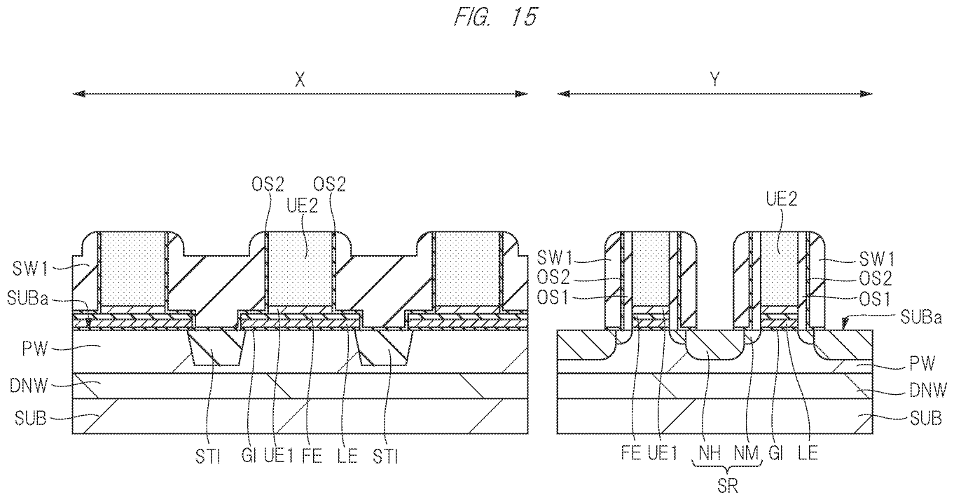

Next, as shown in FIG. 15, the n-type high-concentration semiconductor region NH is formed in the semiconductor substrate SUB in the region sandwiched by the side wall insulating films SW1 formed on the side walls of the first structures in the Y direction. Then, the semiconductor region SR is formed by the low-concentration semiconductor region NM and the high-concentration semiconductor region NH.

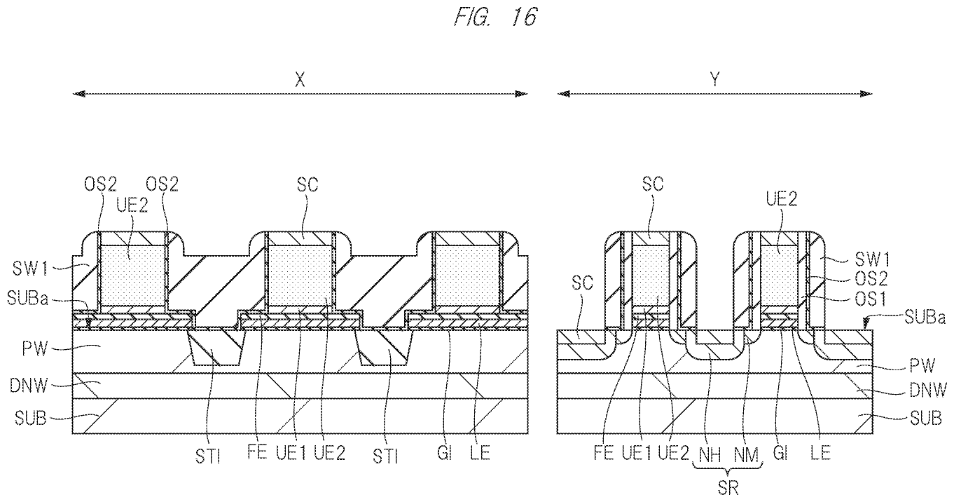

Next, as shown in FIG. 16, the silicide layer SC is formed on the surfaces of the upper layer electrode UE2 and the high-concentration semiconductor region NH.

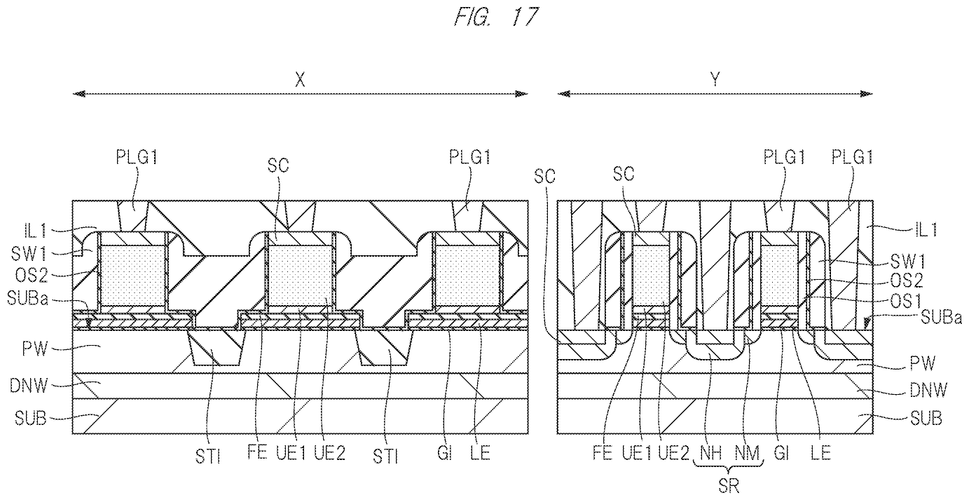

Next, as shown in FIG. 17, the interlayer insulating film IL1 including the plurality of plug electrodes PLG1 is formed. The plug electrode PLG1 is connected to the silicide layer SC formed on the surface of the upper layer electrode UE2 or the high-concentration semiconductor region NH.

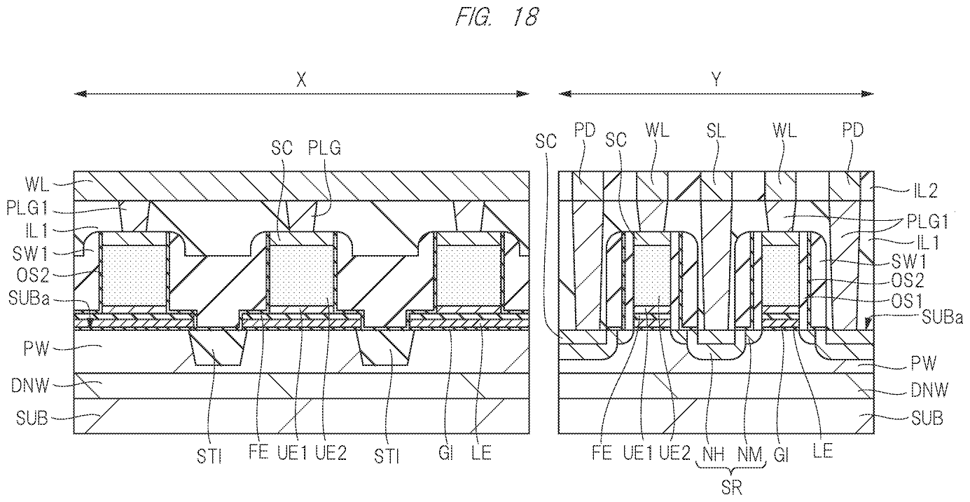

Next, as shown in FIG. 18, the interlayer insulating film IL2 including a plurality of wirings is formed on the interlayer insulating film IL1 and the plug electrode PLG1. The plurality of wirings include the word line WL, the source line SL, and the pad layer PD.

Next, as shown in FIG. 3, the interlayer insulating film IL3 including the plurality of plug electrodes PLG2 is formed on the interlayer insulating film IL2 including the plurality of wirings, and the interlayer insulating film IL4 including wirings is further formed on the interlayer insulating film IL3. The wirings include the bit line BL.

The semiconductor device of the present embodiment is manufactured through the process described above.

In the Y cross-sectional view of FIG. 8, the patterning of the insulating film ZF1 is not indispensable, and it is also possible to form the first structure by patterning the polycrystalline silicon film PS, the metal film ML2, the insulating film ZF2, and the metal film ML1. Further, also in FIG. 10, the patterning of the insulating film ZF1 is not indispensable, and it is also possible to form the second structure by patterning the polycrystalline silicon film PS, the metal film ML2, the insulating film ZF2, and the metal film ML1. In that case, the first structure and the second structure include the lower layer electrode LE, the ferroelectric film FE, the upper layer electrode UE1, and the upper layer electrode UE2 formed in this order from the side of the main surface SUBa of the semiconductor substrate SUB.

Further, in FIG. 10 and FIG. 11, the width W1 of the lower layer electrode LE and the width W2 of the upper layer electrode UE are defined in the X direction by one patterning and isotropic etching, but the lower layer electrode LE having the width W1 and the upper layer electrode UE having the width W2 may be formed by using respectively different patterning (patterning twice in total).

### Features of Method of Manufacturing Semiconductor Device According to Present Embodiment

The first structure having the length L1 in the Y direction and extending in the X direction is formed by patterning the stacked film composed of the insulating film ZF1, the metal film ML1, the insulating film ZF2, the metal film ML2, and the polycrystalline silicon film PS. Next, by patterning the first structure in the X direction, the second structure having the width W1 in the X direction is formed, and then the metal film ML2 and the polycrystalline silicon film PS having the width W2 smaller than the width W1 in the X direction are formed. By forming the gate insulating film GI, the lower layer electrode LE, the ferroelectric film FE, and the upper layer electrodes UE1 and UE2 shown in FIG. 3 by these processes, the area ratio of the memory cell MC larger than 1 ((SI/SF)>1) is realized, and the cell size can be reduced. Therefore, the high reliability and the miniaturization of the semiconductor device can be realized.

As described with reference to FIG. 10 and FIG. 11, since the width W1 of the lower layer electrode LE and the width W2 of the upper layer electrode UE in the X direction are defined by one patterning and isotropic etching, the number of photomasks used in the photolithography process can be reduced as compared with the case of forming them by performing the patterning twice.

As described with reference to FIG. 11 and FIG. 12, since the offset spacer OS1 made of a silicon nitride film is formed on the side wall of the first structure in the process of thinning the polycrystalline silicon film PS, it is possible to prevent the main surface SUBa of the semiconductor substrate SUB from being etched and scraped, and to reduce the defects in the semiconductor device.

Further, as described with reference to FIG. 14, the manufacturing yield of the semiconductor device can be improved by filling the space between the two adjacent upper layer electrodes UE2 in the X direction with the side wall insulating film SW1 so as not to form the “blowhole” in the space.

<First Modification>

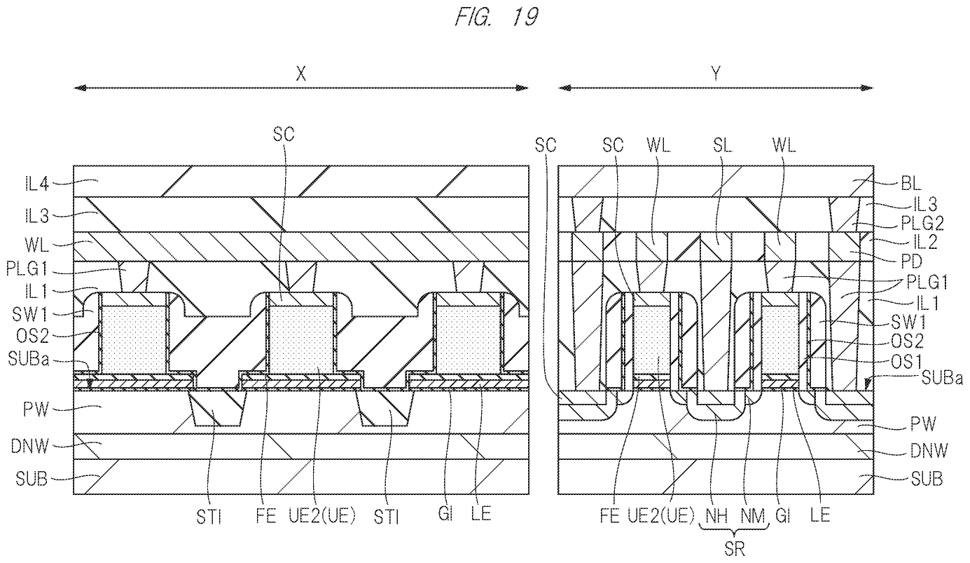

Since the first modification is a modification of the embodiment described above, the difference from the embodiment described above will be described. FIG. 19 is a cross-sectional view showing the configuration of the principal part of the semiconductor device according to the first modification. In the semiconductor device according to the first modification, the upper layer electrode UE constituting the memory cell MC is composed of the upper layer electrode UE2, and the upper layer electrode UE1 is not provided. The memory cell MC includes the gate insulating film GI formed on the upper surface SUBa of the semiconductor substrate SUB, the lower layer electrode LE provided on the gate insulating film GI, the ferroelectric film FE provided on the lower layer electrode LE, the upper layer electrode UE2 provided on the ferroelectric film FE, and the pair of semiconductor regions SR provided in the semiconductor substrate SUB. The upper layer electrode UE2 is provided on the ferroelectric film FE, and is in contact with the ferroelectric film FE.

The method of manufacturing the semiconductor device according to the first modification corresponds to the method in which the step of depositing and processing the metal film ML2 is omitted from the method of manufacturing the semiconductor device according to the embodiment described above.

According to the first modification, since the film thickness of the interlayer insulating film IL1 can be reduced by the film thickness of the upper layer electrode UE1, the aspect ratio of the opening provided in the interlayer insulating film IL1 for providing the plug electrode PLG1 can be reduced, and the manufacturing yield can be improved.

<Second Modification>

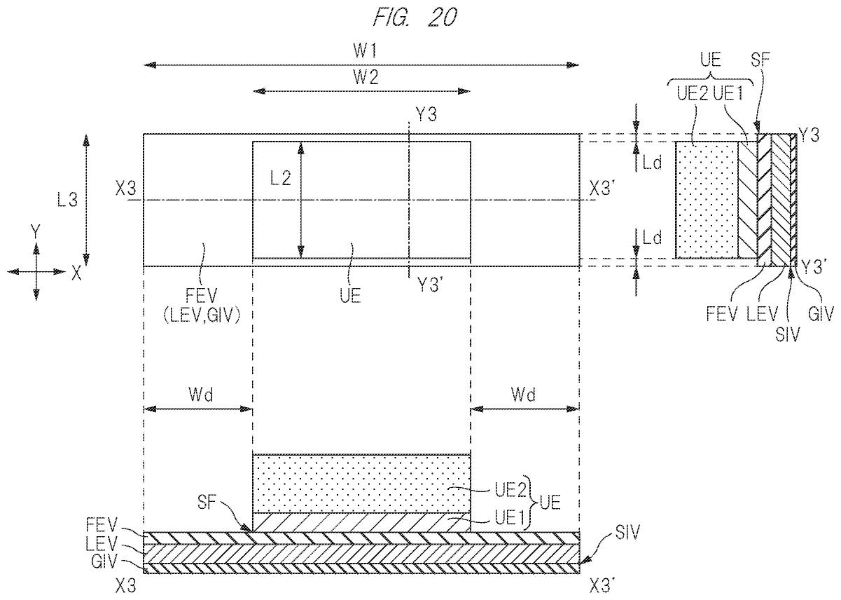

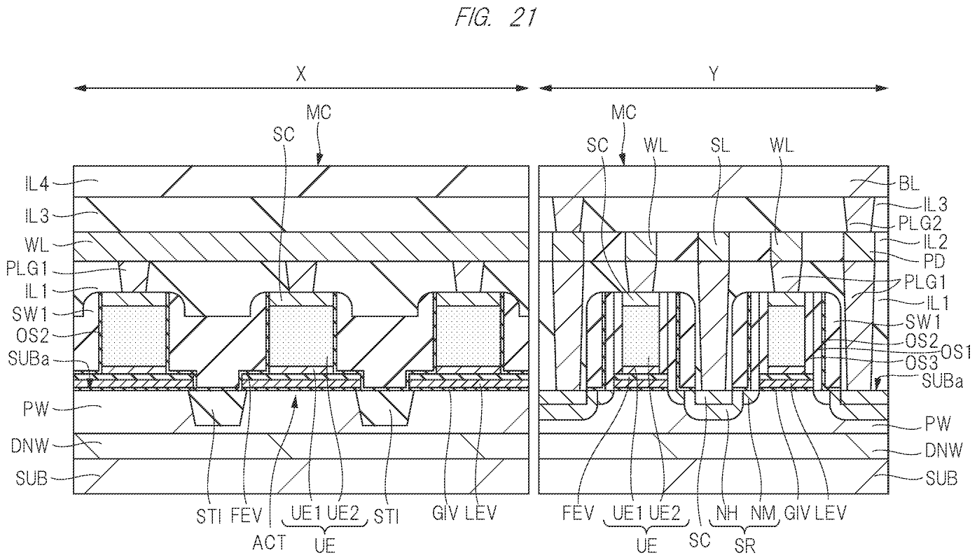

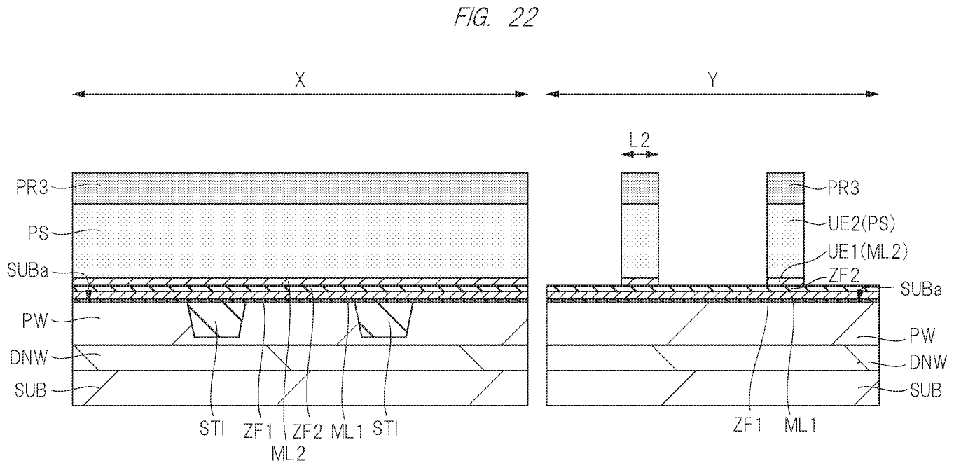

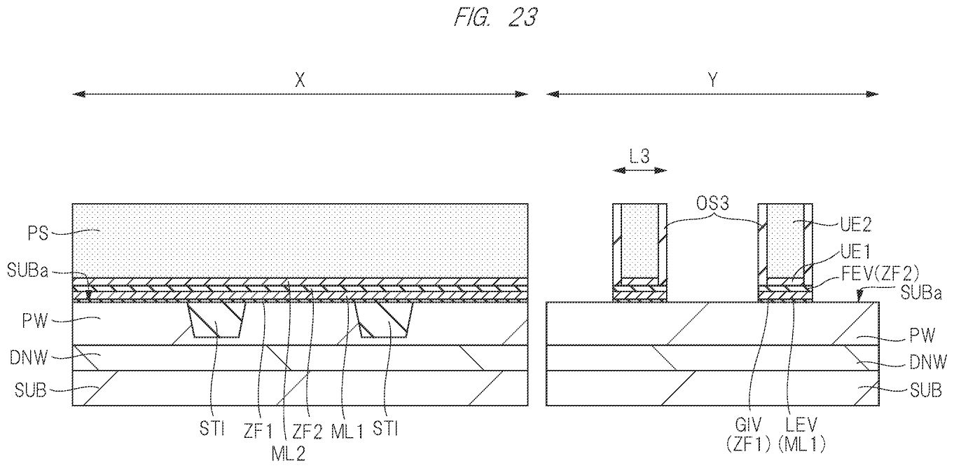

Since the second modification is a modification of the embodiment described above, the difference from the embodiment described above will be described. FIG. 20 is a plan view and a cross-sectional view showing the configuration of the principal part of the semiconductor device according to the second modification. FIG. 21 is a cross-sectional view showing the configuration of the principal part of the semiconductor device according to the second modification, and FIG. 22 and FIG. 23 are cross-sectional views showing the manufacturing process of the semiconductor device according to the second modification.

As shown in FIG. 20, in the semiconductor device according to the second modification, the length L3 of the ferroelectric film FEV, the lower layer electrode LEV, and the gate insulating film GIV in the Y direction is larger than the length L2 of the upper layer electrode UE in the Y direction (L3>L2). In a plan view, the upper layer electrode UE and the ferroelectric film FEV each have a substantially rectangular shape having the long side in the X direction and the short side in the Y direction. Also, in a plan view, the upper layer electrode UE is included in the ferroelectric film FEV, the long sides of the upper layer electrode UE have the separation distance Ld from the long sides of the ferroelectric film FEV, and the short sides of the upper layer electrode have the separation distance Wd from the short sides of the ferroelectric film FEV. Here, the separation distance Ld between the long sides is smaller than the separation distance Wd between the short sides (Ld<Wd). As described in the above embodiment, the separation distance Wd between the short sides is set for the purpose of realizing the area ratio (SIV/SF) larger than 1 ((SIV/SF)>1), and is a relatively large value. On the other hand, the separation distance Ld between the long sides is necessary so as to prevent the ferroelectric film FEV in the vicinity of the long side from acting as a film that retains the above-mentioned first polarization state or second polarization state. Therefore, a relatively small value is sufficient as the separation distance Ld. Note that the substantially rectangular shape includes a rounded rectangle other than that having 90° at the corners.

As shown in the Y cross-sectional view of FIG. 21, the offset spacer OS3 is provided on the side wall of the upper layer electrode UE, and the offset spacers OS1 and OS2 and the side wall insulating film SW1 are provided on the side wall of the structure composed of the gate insulating film GIV, the lower layer electrode LEV, the ferroelectric film FEV, the upper layer electrode UE, and the offset spacer OS3. Namely, the structure composed of the gate insulating film GIV, the lower layer electrode LEV, the ferroelectric film FEV, the upper layer electrode UE, and the offset spacer OS3 corresponds to the first structure in the embodiment described above.

The method of manufacturing the semiconductor device according to the second modification is different in the manufacturing process of the first structure described with reference to FIG. 8 in the manufacturing method of the embodiment described above. As shown in FIG. 22 and FIG. 23, in the second modification, the polycrystalline silicon film PS and the metal film ML2 are patterned so as to have the length L2 in the Y direction. In the Y direction, the upper layer electrode UE2 made of the polycrystalline silicon film PS and the upper layer electrode UE1 made of the metal film ML2 are formed. Next, as shown in FIG. 23, the offset spacers OS3 are formed on the side walls of the upper layer electrodes UE1 and UE2, and the insulating film ZF2, the metal film ML1, and the insulating film ZF1 in the regions exposed from the upper layer electrodes UE1 and UE2 and the offset spacers OS3 are etched, thereby forming the ferroelectric film FEV, the lower layer electrode LEV, and the gate insulating film GIV having the length L3 in the Y direction. Next, the process after the step of forming the offset spacers OS1 shown in FIG. 9 described in the above embodiment is performed.

According to the second modification, as described with reference to FIG. 20, the long sides of the upper layer electrode UE have the separation distance Ld from the long sides of the ferroelectric film FEV, and the short sides of the upper layer electrode UE have the separation distance Wd from the short sides of the ferroelectric film FEV. In this way, since the ferroelectric film FEV in the vicinity of the long side and the short side of the ferroelectric film FEV is prevented from acting as the film that retains the above-mentioned first polarization state or second polarization state, the polarization retention characteristics of the ferroelectric film FEV can be improved. This is because the ferroelectric film FEV in the vicinity of the long side and the short side is damaged by etching during processing, and has lower polarization retention characteristics than the central portion.

<Third Modification>

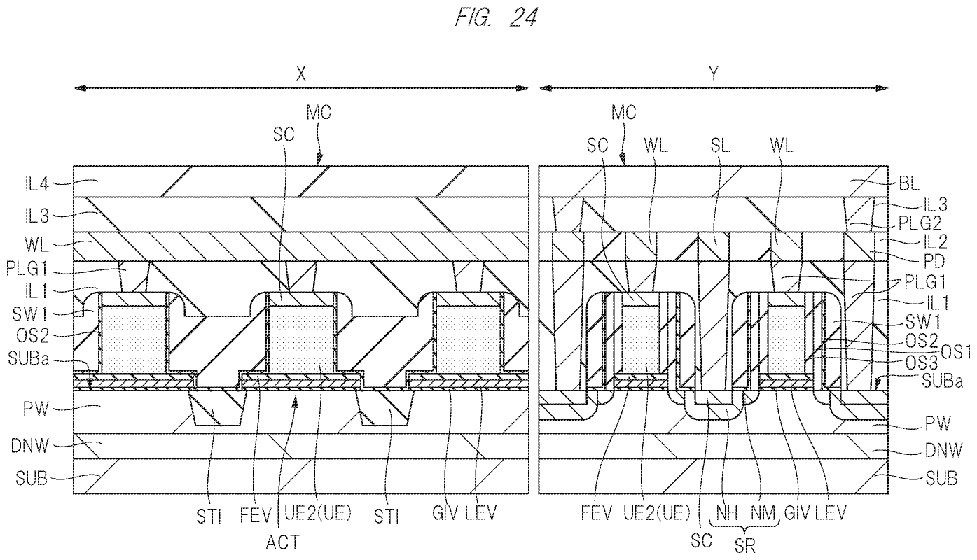

Since the third modification is a modification of the second modification described above, the difference from the second modification described above will be described. FIG. 24 is a cross-sectional view showing the configuration of the principal part of the semiconductor device according to the third modification. As in the first modification, the upper layer electrode UE constituting the memory cell MC is composed of the upper layer electrode UE2, and the upper layer electrode UE1 is not provided. The memory cell MC includes the gate insulating film GIV formed on the upper surface SUBa of the semiconductor substrate SUB, the lower layer electrode LEV provided on the gate insulating film GIV, the ferroelectric film FEV provided on the lower layer electrode LEV, the upper layer electrode UE2 provided on the ferroelectric film FEV, and the pair of semiconductor regions SR provided in the semiconductor substrate SUB. The upper layer electrode UE2 is provided on the ferroelectric film FEV, and is in contact with the ferroelectric film FEV.

The method of manufacturing the semiconductor device according to the third modification corresponds to the method in which the step of depositing and processing the metal film ML2 is omitted from the method of manufacturing the semiconductor device according to the second modification described above.

In the foregoing, the invention made by the inventors has been specifically described based on the embodiments, but it goes without saying that the present invention is not limited to the embodiments described above and can be variously modified within the range not departing from the gist thereof.

For example, although the various modifications have been described above, a part or all of the modifications described above can be applied in combination within the range not contradicting with the gist described for each modification.

What is claimed is:

1. A semiconductor device comprising:
a semiconductor substrate having a main surface;
a plurality of word lines provided on the main surface and extending in a first direction in a plan view;
a plurality of bit lines provided on the main surface and extending in a second direction orthogonal to the first direction in a plan view; and
a plurality of memory cells arranged in matrix in the first direction and the second direction,
wherein the memory cell included in the plurality of memory cells includes:
a gate insulating film provided on the main surface;
a lower layer electrode provided on the gate insulating film;
a ferroelectric film provided on the lower layer electrode;
an upper layer electrode provided on the ferroelectric film; and
a pair of semiconductor regions provided so as to sandwich the lower layer electrode in the second direction,
wherein the upper layer electrode is connected to one word line included in the plurality of word lines, and
wherein a first width of the lower layer electrode in the first direction is larger than a second width of the upper layer electrode in the first direction in a plan view.

2. The semiconductor device according to claim 1,
wherein, in the adjacent memory cells connected to the one word line, the lower layer electrodes are separated from each other and the upper layer electrodes are separated from each other.

3. The semiconductor device according to claim 1,
wherein an area ratio (SI/SF) of a first contact area (SI) between the lower layer electrode and the gate insulating film and a second contact area (SF) between the upper layer electrode and the ferroelectric film is larger than 1.

4. The semiconductor device according to claim 1,
wherein the upper layer electrode has a stacked structure of a first upper layer electrode provided on the ferroelectric film and a second upper layer electrode provided on the first upper layer electrode.

5. The semiconductor device according to claim 1,
wherein a first length of the lower layer electrode in the second direction is equal to a second length of the upper layer electrode in the second direction in a plan view.

6. The semiconductor device according to claim 1,
wherein a first length of the lower layer electrode in the second direction is larger than a second length of the upper layer electrode in the second direction in a plan view.

7. The semiconductor device according to claim 6,
wherein the upper layer electrode has a stacked structure of a first upper layer electrode provided on the ferroelectric film and a second upper layer electrode provided on the first upper layer electrode.

8. A method of manufacturing a semiconductor device comprising a memory cell, the memory cell including a gate insulating film provided on a main surface of a semiconductor substrate, a lower layer electrode provided on the gate insulating film, a ferroelectric film provided on the lower layer electrode, an upper layer electrode provided on the ferroelectric film, and a pair of semiconductor regions arranged so as to sandwich the lower layer electrode in a plan view, the method comprising steps of:
(a) sequentially forming a first insulating film, a first metal film, a second insulating film, and a conductor film on the main surface of the semiconductor substrate;
(b) patterning the conductor film, the second insulating film, and the first metal film, thereby forming a first structure extending in a first direction of the main surface and having a first length in a second direction orthogonal to the first direction;
(c) patterning the first structure, thereby forming a second structure having a first width in the first direction; and
(d) performing etching process to the conductor film included in the second structure, thereby forming the conductor film having a second width smaller than the first width in the first direction,
wherein the gate insulating film is formed of the first insulating film, the lower layer electrode is formed of the first metal film, the ferroelectric film is formed of the second insulating film, and the upper layer electrode is formed of the conductor film.

9. The method of manufacturing the semiconductor device according to claim 8,
wherein the conductor film is a stacked film of a second metal film formed on the second insulating film and a polycrystalline silicon film formed on the second metal film, and
wherein the step (d) includes steps of:
(d1) performing etching process to the polycrystalline silicon film included in the second structure, thereby processing the polycrystalline silicon film to have the second width smaller than the first width in the first direction; and
(d2) after the step (d1), processing the second metal film to have the second width so as to overlap with the polycrystalline silicon film.

10. The method of manufacturing the semiconductor device according to claim 8, further comprising, between the steps (b) and (c), a step of:
(e) forming offset spacers on side walls of the first structure.

11. The method of manufacturing the semiconductor device according to claim 10,
wherein the offset spacer is made of a silicon nitride film.

12. A method of manufacturing a semiconductor device comprising a memory cell, the memory cell including a gate insulating film provided on a main surface of a semiconductor substrate, a lower layer electrode provided on the gate insulating film, a ferroelectric film provided on the lower layer electrode, an upper layer electrode provided on the ferroelectric film, and a pair of semiconductor regions arranged so as to sandwich the lower layer electrode in a plan view, the method comprising steps of:
(a) sequentially forming a first insulating film, a first metal film, a second insulating film, and a conductor film on the main surface of the semiconductor substrate;
(b) patterning the conductor film, thereby forming a first structure extending in a first direction of the main surface and having a first length in a second direction orthogonal to the first direction;
(c) forming first offset spacers on side walls of the first structure;
(d) patterning the second insulating film and the first metal film with using the first structure and the first offset spacers as a mask, thereby forming a second structure having a second length larger than the first length in the second direction;
(e) patterning the second structure, thereby forming a third structure having a first width in the first direction; and
(f) performing etching process to the conductor film included in the third structure, thereby forming the conductor film having a second width smaller than the first width in the first direction,
wherein the gate insulating film is formed of the first insulating film, the lower layer electrode is formed of the first metal film, the ferroelectric film is formed of the second insulating film, and the upper layer electrode is formed of the conductor film.

13. The method of manufacturing the semiconductor device according to claim 12,
wherein the conductor film is a stacked film of a second metal film formed on the second insulating film and a polycrystalline silicon film formed on the second metal film, and
wherein the step (f) includes steps of:
(f1) performing etching process to the polycrystalline silicon film included in the third structure, thereby processing the polycrystalline silicon film to have the second width smaller than the first width in the first direction; and
(f2) after the step (f1), processing the second metal film to have the second width so as to overlap with the polycrystalline silicon film.

14. The method of manufacturing the semiconductor device according to claim 12, further comprising, between the steps (d) and (e), a step of:
(g) forming second offset spacers on side walls of the second structure.

15. The method of manufacturing the semiconductor device according to claim 14,
wherein the second offset spacer is made of a silicon nitride film.
